(19) United States
(12) Patent Application Publication
(10) Pub. No.: US 2011/0150013 A1
(43) Pub. Date: Jun. 23, 2011

(54) RESONANT PUMPING OF THIN-DISK LASER WITH AN OPTICALLY PUMPED EXTERNAL-CAVITY SURFACE-EMITTING SEMICONDUCTOR LASER

(75) Inventors: Luis A. Spinelli, Sunnyvale, CA (US); Andrea Caprara, Palo Alto, CA (US)

(73) Assignee: Coherent, Inc., Santa Clara, CA (US)

(21) Appl. No.: 12/641,184

(22) Filed: Dec. 17, 2009

(51) Int. Cl. H01S 3/098; H01S 3/091; H01S 5/026

(52) U.S. Cl. 372/18; 372/70; 372/45.01; 372/98; 372/93; 372/50.22

(57) ABSTRACT

Laser apparatus comprises a solid-state laser-resonator including a thin-disk solid-state gain-medium. The thin-disk gain medium is optically pumped using radiation circulating in an OPS-laser resonator. The solid-state laser-resonator can be a passively mode-locked or actively Q-switched laser-resonator.

### TECHNICAL FIELD OF THE INVENTION

The present invention relates in general thin-disk or active-mirror lasers. The invention relates in particular to means for optically pumping such lasers.

### DISCUSSION OF BACKGROUND ART

A thin-disk laser is a laser including a resonator having a resonator-mirror surmounted by a thin disk of a solid-state gain-medium. This is referred to by some practitioners as an “active minor”. The gain-medium is typically a rare earth doped gain-medium, such as Nd:YAG or Yb:YAG, and usually has a thickness no greater than about 2 millimeters (mm). The minor and gain-medium are typically supported on a relatively massive heat-sink, which can be passively or actively cooled. The thinner the disk, the more efficient the cooling.

This heat-sink scheme provides much more efficient cooling than could be provided for a conventional rod-like solid-state gain-medium. This has caused the thin-disk laser to be preferred by some practitioners for scaling to high output powers, for example, greater than about 1 kilowatt (kW) output. Power-scaling aside, using the active mirror at the end of a resonator or in the center of a folded resonator makes it possible to conveniently generate single-longitudinal-mode laser-output.

Usually the thin disk is somewhat more heavily doped than a rod-like gain-medium in order to provide a greater gain per unit length. Nevertheless, because the disk is so thin, absorption of optical pump radiation is inefficient. This has necessitated the development of various schemes for causing pump radiation to make multiple passes through the gain-medium. If, as is preferably the case, it is desired to deposit the pump radiation with a Gaussian distribution, such schemes can become complex and costly. There continues to be a need for a simple pumping scheme for a thin-disk gain-medium that is capable of depositing pump radiation in the gain-medium with a Gaussian or near Gaussian intensity distribution.

### SUMMARY OF THE INVENTION

In one aspect of the present invention, optical apparatus comprises a thin-disk solid-state gain-medium surmounting a mirror. An arrangement is provided for optically energizing the thin-disk gain medium using radiation circulating in an OPS-laser resonator.

The think-disk solid-state gain-medium surmounted minor may be a component of an optical amplifier or a component of a thin-disk solid-state laser resonator. Radiation circulating in an OPS-laser resonator typically has a Gaussian or near Gaussian intensity distribution. Pumping with OPS-laser radiation circulating in a resonator provides that essentially all of the power generated by the OPS-laser resonator is effectively absorbed in the solid-state gain-medium.

In preferred embodiments of the laser apparatus in accordance with the present invention, the solid-state and OPS-laser resonators are folded laser-resonators and the thin-disk solid-state gain-medium surmounted minor is a common fold-minor of the laser resonators. Preferred embodiments of the laser apparatus include embodiments in which the solid-state laser-resonator is a mode-locked laser resonator.

### BRIEF DESCRIPTION OF THE DRAWINGS

The accompanying drawings, which are incorporated in and constitute a part of the specification, schematically illustrate a preferred embodiment of the present invention, and together with the general description given above and the detailed description of the preferred embodiment given below, serve to explain principles of the present invention.

FIG. 1 schematically illustrates one preferred embodiment of an OPS-laser pumped thin-disk laser in accordance with the present invention, including a once-folded thin-disk laser resonator and a once folded OPS-laser resonator, and wherein the active mirror of the thin-disk laser resonator serves as a common fold-mirror for both resonators such that gain-medium of the active minor is resonantly pumped by laser radiation circulating in the OPS-laser resonator.

FIG. 2 is a graph schematically illustrating calculated circulating power in the OPS laser-resonator as a function of circulating power in the thin-disk laser-resonator for values of gain at wavelength of 1030 nm in the thin-disk gain-medium, for one example of the apparatus of FIG. 1 wherein the OPS-laser is arranged to circulate radiation having a wavelength of 1010 nm, and wherein the thin-disk gain-medium is Yb:YAG generating fundamental radiation having a wavelength of 1030 nm.

FIG. 3 is a graph schematically illustrating calculated circulating power in the OPS laser resonator as a function of circulating power in the in the thin-disk laser-resonator for values of round-trip transmission of the thin-disk gain medium for radiation having a wavelength of 1010 nm in the example of FIG. 2.

FIG. 4 is a graph schematically illustrating calculated OPS amplification as a function of circulating power in the OPS-laser resonator in the example of FIG. 2.

FIG. 5 is a graph schematically illustrating a calculated relationship between circulating power in the OPS-laser resonator and circulating power in the thin-disk laser resonator for various values of net round-trip transmission at 1010 nm of the OPS-laser resonator in the example of FIG. 2.

FIG. 6 is a graph schematically illustrating a calculated relationship between circulating power in the OPS-laser resonator and circulating power in the thin-disk laser resonator for various values of round-trip transmission at a wavelength of 1030 nm (output coupling) of the thin-disk laser resonator in the example of FIG. 2.

FIG. 7 is a superposition of the graphs of FIG. 6 and FIG. 7 schematically illustrating determination of an optimum operating condition for the OPS laser-resonator and the thin-disk laser-resonator in the example of FIG. 2.

FIG. 8 is a graph schematically illustrating calculated output power of the thin-disk laser, power extracted from the thin-disk gain-medium, power circulating in the thin-disk laser resonator, power circulating in the OPS-laser resonator, and OPS-laser power absorbed in the thin-disk gain-medium as a function of transmission of the output coupling mirror for an example of the apparatus of the laser of FIG. 1 wherein the OPS-laser resonator is configured such that circulating OPS-laser radiation has a beam radius of 150 micrometers (μm) on the thin-disk gain-medium.

FIG. 9 is a graph similar to the graph of FIG. 8, but wherein the OPS-laser resonator is configured such that circulating OPS-laser radiation has a beam radius of 200 μm on the thin-disk gain-medium.

FIG. 10 is a graph similar to the graph of FIG. 8, but wherein the OPS-laser resonator is configured such that circulating OPS-laser radiation has a beam radius of 250 μm on the thin-disk gain-medium.

FIG. 11 schematically illustrates a detailed experimental layout for the laser in accordance with the present invention depicted in principle in FIG. 1.

FIG. 11A and FIG. 11B are graphs schematically illustrating beam radius as a function of resonator length in the pump (OPS) laser-resonator and the thin-disk laser resonator respectively of FIG. 11.

FIG. 12 schematically illustrates another preferred embodiment of an OPS-laser pumped thin-disk laser in accordance with the present invention, similar to the laser of FIG. 1 but wherein the active mirror is resonantly pumped by two once-folded OPS-laser resonators each thereof folded by the active minor.

FIG. 13 schematically illustrates yet another embodiment of an OPS-laser pumped thin-disk laser in accordance with the present invention similar to the laser of FIG. 1 but wherein the OPS-laser resonator is configured to include two OPS-chips

FIG. 14 schematically illustrates a still yet another preferred embodiment of an OPS-laser pumped thin-disk laser in accordance with the present invention, similar to the laser of FIG. 1, but wherein the thin-disk laser resonator includes a Kerr effect element cooperative with an aperture stop to provide Kerr lens passive mode-locking of the thin-disk laser resonator.

FIG. 15 schematically illustrates a further embodiment of an OPS-laser pumped thin-disk laser in accordance with the present invention, similar to the laser of FIG. 1 but wherein the thin-disk laser resonator is twice folded and terminated at one end thereof by a saturable Bragg reflector for providing passive mode-locking of the thin-disk laser resonator.

FIG. 16 schematically an embodiment of an OPS-laser pumped thin-disk amplifier in accordance with the present invention.

### DETAILED DESCRIPTION OF THE INVENTION

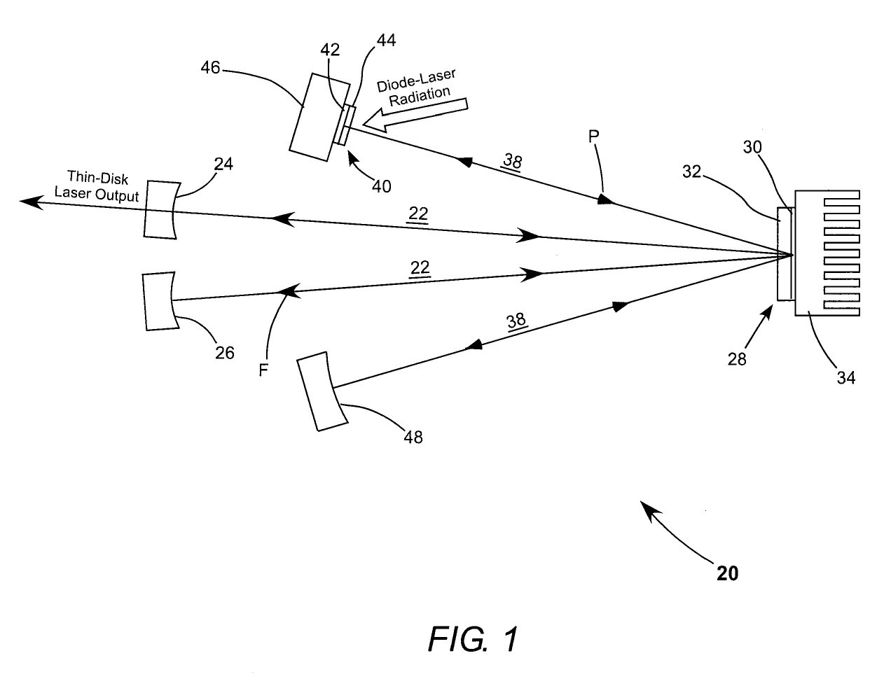

Referring now to the drawings, wherein like components are designated by like reference numerals, FIG. 1 schematically illustrates one preferred embodiment 20 of an OPS-laser pumped thin-disk laser in accordance with the present invention. Laser 20 includes a once-folded thin-disk laser resonator 22 terminated by concave minors 24 and 26. Resonator 22 is folded by an active mirror 28 formed by a minor 30 surmounted by a thin-disk (solid-state) gain-medium 32A. The active minor is cooled by a heat-sink 34. It should be noted that while such a gain-medium is referred to here, and commonly in the art, as a disk, the gain-medium does not have to be circular in outline, but could have a rectangular, polygonal shape, or some other non-circular shape.

A once-folded OPS-laser resonator 38 includes an OPS-structure (OPS-chip) 40. OPS-structure 40 includes a mirror-structure 42 surmounted by a multilayer semiconductor gain-structure 44 including active or quantum well (W) layers (not shown) spaced apart by spacer layers (also not shown). The Ops-chip is bonded to a heat-sink 46. Gain-structure 44 is energized (optically pumped) by radiation from a diode-laser array. The radiation can be fiber-delivered or directly focused. In response to the optical pumping, the gain-structure generates radiation at a fundamental wavelength which can be selected by selecting an appropriate composition of the QW-layers. Resonator 38 is terminated by mirror-structure 42 of the OPS-chip and a concave minor 48. Resonator 38 is folded by mirror 30 of active minor 28. OPS-laser radiation circulates in the resonator 38 as indicated by arrowheads P.

It should be noted here that only sufficient description of an OPS-laser is provided above for describing principles of the present invention. A detailed description of OPS-lasers is provided in U.S. Pat. No. 6,097,742 assigned to the assignee of the present invention, and the complete disclosure of which is hereby incorporated by reference.

A portion of circulating OPS-laser radiation P is absorbed by thin-disk gain-medium 32 of active minor 28 and energizes (optically pumps) the gain-medium causing radiation F, having a fundamental wavelength characteristic of the gain-medium, to circulate in resonator 22. Mirror 24 of resonator 22 is partially transparent, as a result of which, a portion of radiation F is delivered from the resonator as output radiation.

In resonator 38, mirror-structure 42 and mirror 48 are maximally reflective for the circulating OPS-laser radiation. OPS-laser radiation is coupled out of the resonator directly into the thin-disk gain-medium by absorption therein. This is a significant improvement over prior-art thin-disk laser pumping schemes wherein pump radiation is delivered from a laser and then caused to make two or more passes through the thin-disk by a separate arrangement of mirrors.

One advantage of the inventive direct resonant pumping scheme is that, because of the resonant build up of pump-radiation P in resonator 22, and corresponding multiple passes of the pump-radiation through the thin-disk gain medium, a relatively high pump-power can be absorbed in the thin-disk gain at wavelengths for which the thin-disk has a relatively low absorption cross-section. This provides that the thin-disk gain-medium can be pumped at a wavelength relatively close to the emission wavelength (lasing wavelength) of the gain-medium which minimizes the quantum defect and, accordingly, minimizes heat build-up in the disk.

While the apparatus of FIG. 1 may appear relatively simple in layout, it is far from simple functionally. In order for the apparatus to function optimally, both the thin disk resonator and the OPS-laser resonator must function optimally, but each of resonators is strongly influenced by what goes on in the other. Accordingly, values including gain in each resonator, absorption in the thin-disk, OPS-laser beam size on the thin disk and output coupling from the thin-disk laser resonator must all be carefully balanced and coordinated.

Set forth below is a description of a graphical theoretical analysis of an example of apparatus 20 which determines relationships between the several variables and preferred operating parameters and estimates output of the thin-disk laser resonator. The analysis assumes that the thin-disk gain-medium is ytterbium-doped yttrium aluminum garnet (Yb:YAG) having a fundamental laser wavelength of 1030 nm, and that the OPS-laser resonator is configured to generate pump radiation having a wavelength of 1010 nm. It is assumed that the OPS gain-structure is pumped with 40 Watts (W) of continuous wave (CW) diode-laser radiation.

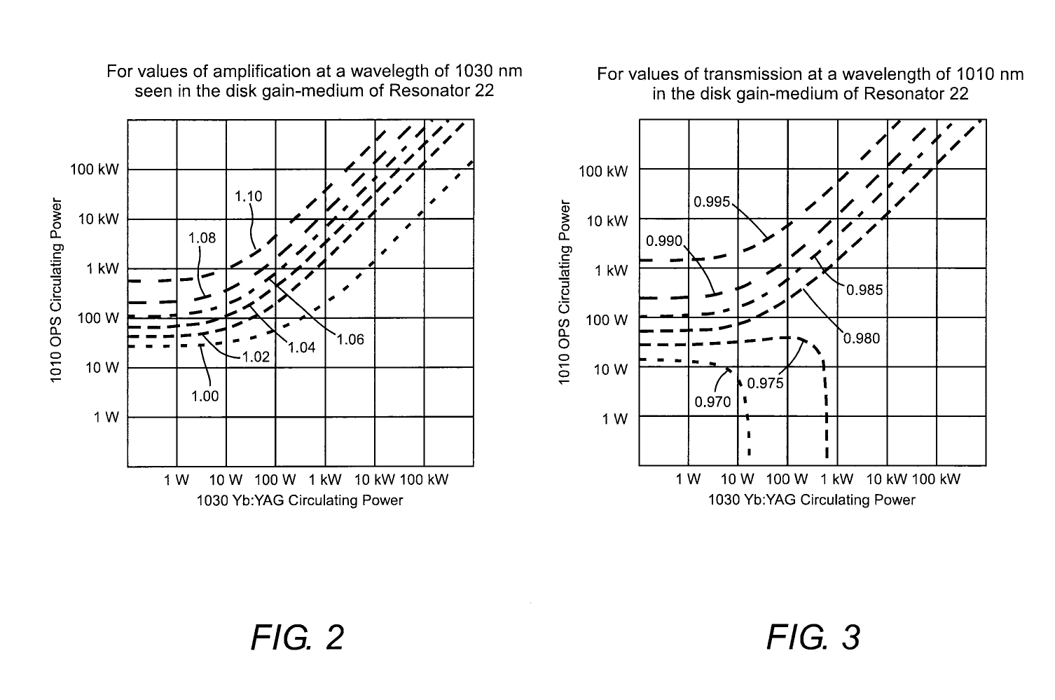

FIG. 2 is a graph schematically illustrating calculated circulating power in OPS laser-resonator 38 as a function of circulating power in the thin-disk laser-resonator 22 for values of gain at wavelength of 1030 nm in the thin-disk gain-medium, for one example of the apparatus of FIG. 1 wherein the OPS-laser is arranged to circulate radiation having a wavelength of 1010 nm, and wherein the thin-disk gain-medium is Yb:YAG generating fundamental radiation having a wavelength of 1030 nm. This graph essentially illustrates how thin disk laser resonator 22 behaves, on a stand-alone basis, from the point of view of 1030 nm radiation, considering only gain.

FIG. 3 is a graph schematically illustrating calculated circulating power in the OPS laser-resonator as a function of circulating power in the in the thin-disk laser-resonator for values of round-trip transmission of the thin-disk gain medium for radiation having a wavelength of 1010 nm in the example of FIG. 2. This graph essentially illustrates how thin disk laser resonator 22 behaves, on a stand-alone basis, from the point of view of 1010 nm radiation, considering only loss in the OPS laser-resonator. Circulating power in the OPS-laser resonator however at any given pump radiation power delivered to the OPS-chip is a function of the loss in the OPS laser-resonator.

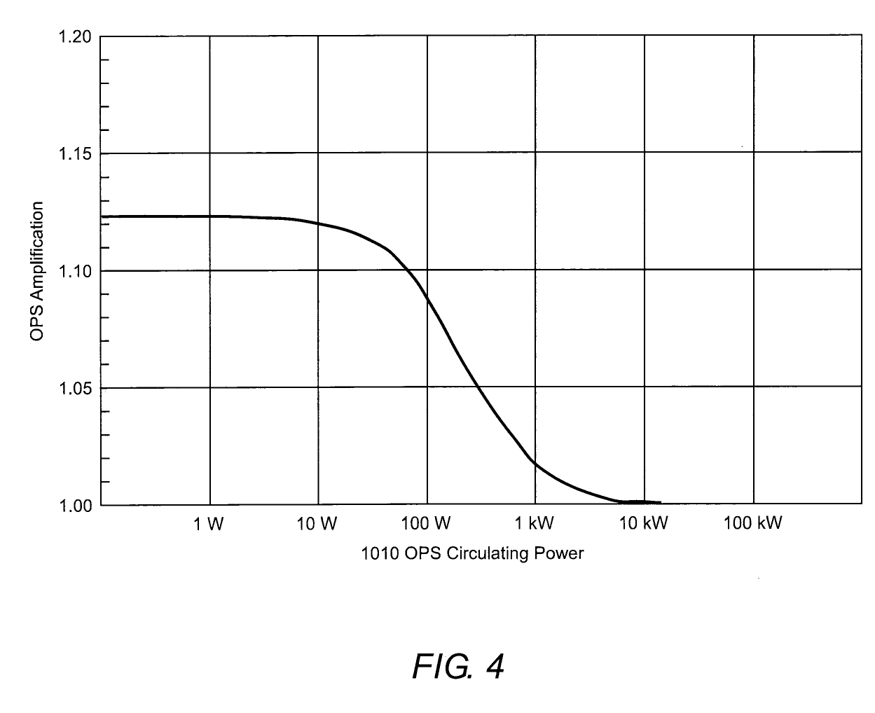

FIG. 4 is a graph schematically illustrating calculated amplification of OPS-laser chip as a function of circulating power in the OPS-laser resonator, for 40 W of diode-laser pumping. It is assumed here that the 40 W of diode-laser radiation forms a pump spot having a radius of 400 μm on the OPS-chip. The power roll-off in the graph illustrates the gain-saturation behavior of the OPS chip.

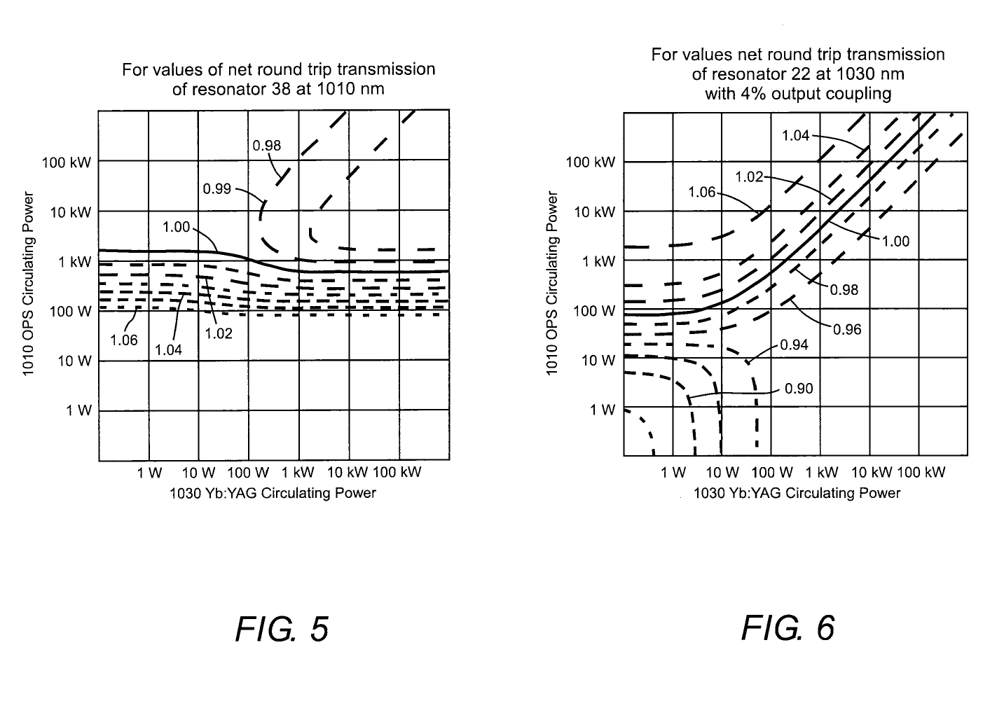

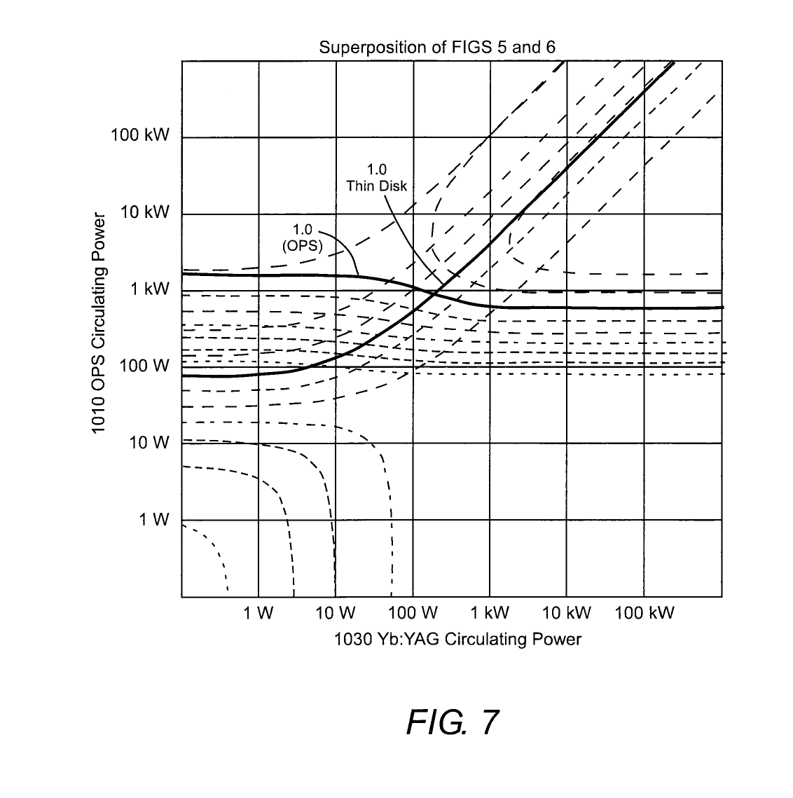

In order to calculate the behavior of the thin-disk laser resonator for the fixed diode-laser pump power it is necessary essentially to multiply the values of the graph of FIG. 3 by the vales of the graph of FIG. 4. The result of this is depicted in the graph of FIG. 5, which schematically illustrates the calculated circulating power in the OPS laser-resonator as a function of circulating power in the thin-disk laser resonator for various values of net round trip transmission (loss times gain) at the OPS-laser wavelength of 1010 nm. This shows how the OPS resonator 38 could operate if there were no dependence of this operation on thin-disk laser resonator 22. The resonator would operate in steady-state (CW) conditions at any set of circulating power conditions along the net round trip transmission value of 1.0 (loss=gain) depicted by a solid curve. As there is a dependence on the operation of the thin-disk laser resonator, however, this operation needs to be taken into account, as follows.

FIG. 6 is a graph schematically illustrating the calculated circulating power in OPS-laser resonator as a function of circulating power in the thin-disk laser resonator for values of net round-trip transmission (loss multiplied by gain) at 1030 nm in the disk laser resonator. It is assumed that output coupling in resonator 22 is 4% and that the OPS-laser beam has a radius of 200 μm. This shows how thin-disk laser resonator 22 could operate if there were no dependence of this operation on OPS laser-resonator 38. Here again, the thin-disk laser-resonator resonator would operate in CW conditions at any set of circulating power conditions along the net round trip transmission value of 1.0 (solid curve).

As far as the inventive apparatus is concerned, CW operation occurs only when the net round-trip transmission for both resonators 38 and 22 is equal to 1.0. This is depicted graphically in FIG. 7, which is a superposition of the graphs of FIG. 5 and FIG. 6. In FIG. 7, curves for all other round-trip values but the solid curves for value 1.0 have been subdued. This superposition predicts steady state operation for both resonators will occur (assuming 40 W pump radiation delivered to the OPS-chip, and 4% output coupling in resonator 22) with about 800 W circulating in the OPS laser-resonator and about 250 W circulating in the thin-disk laser-resonator.

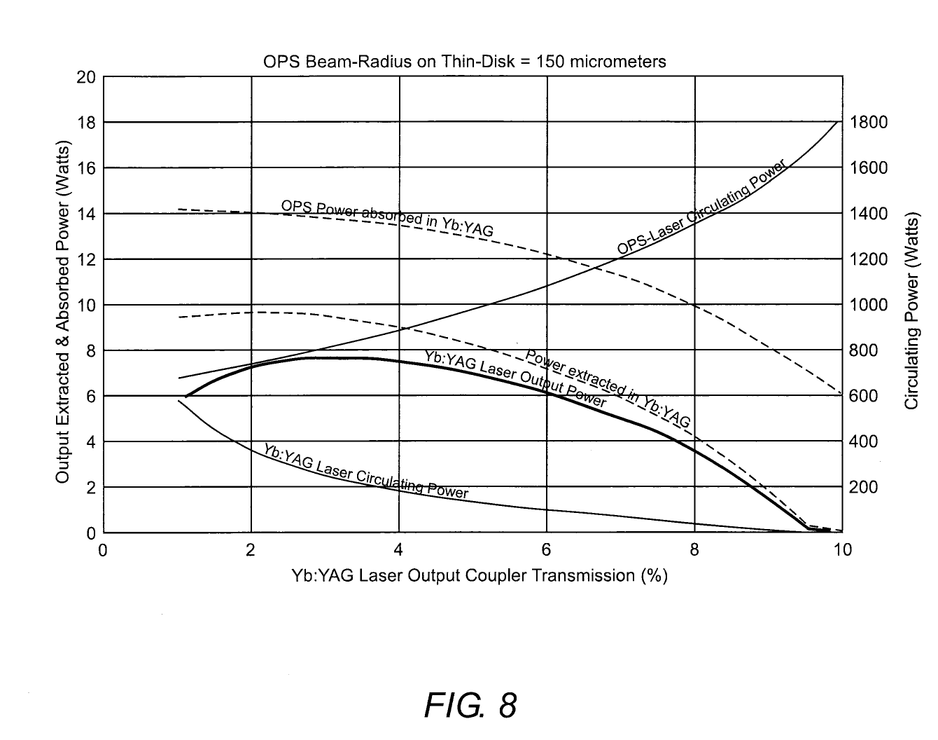

FIG. 8 is a graph schematically illustrating calculated output power of the thin-disk laser, power extracted from thin-disk gain-medium 32, power circulating in thin-disk laser resonator 22, power circulating in OPS-laser resonator 38, and OPS-laser power absorbed in the thin-disk gain-medium as a function of transmission of output coupling minor 24 of resonator 22 for an example of the apparatus of the laser of FIG. 1 wherein the OPS-laser resonator is configured such that circulating OPS-laser radiation has a beam radius of 150 μm on the thin-disk gain-medium. It can be seen that the peak power output is obtained with 3% output coupling from minor 24 with about 800 W circulating in resonator 38 and about 250 W circulating in resonator 22 consistent with the prediction of FIG. 7.

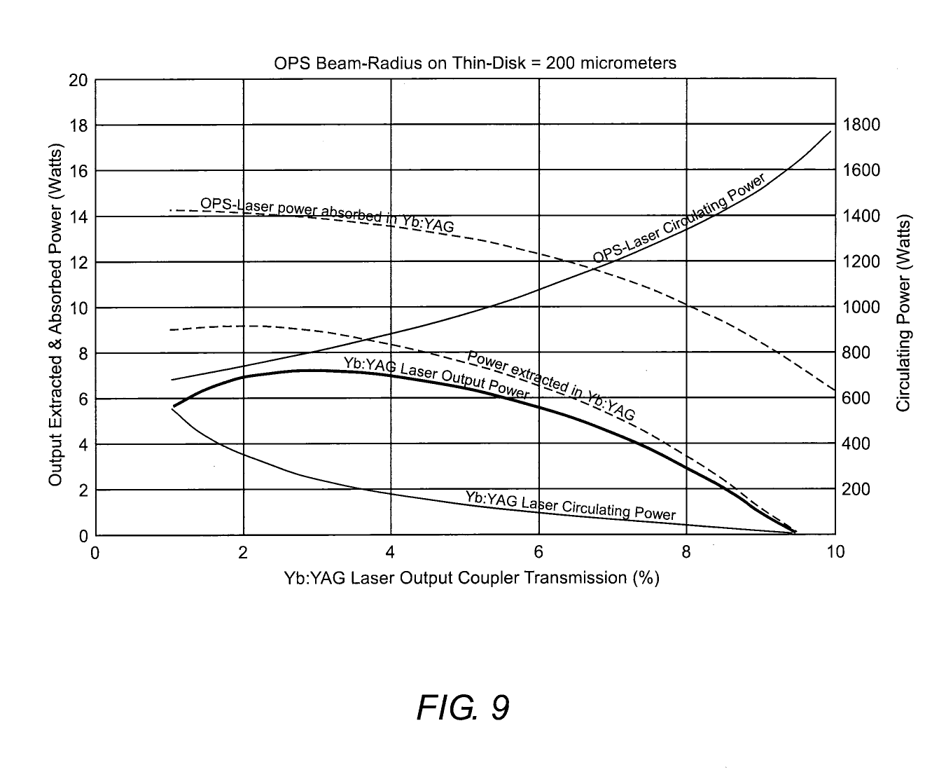

FIG. 9 is a graph similar to the graph of FIG. 8, but wherein the OPS-laser beam radius is assumed to be 200 μm. It can be seen that the peak power output is again obtained with 3% output coupling from mirror 24 with about 800 W circulating in resonator 38 and about 250 W circulating in resonator 22. The peak power, however, is somewhat lower than is the case with the 150 μm diameter beam.

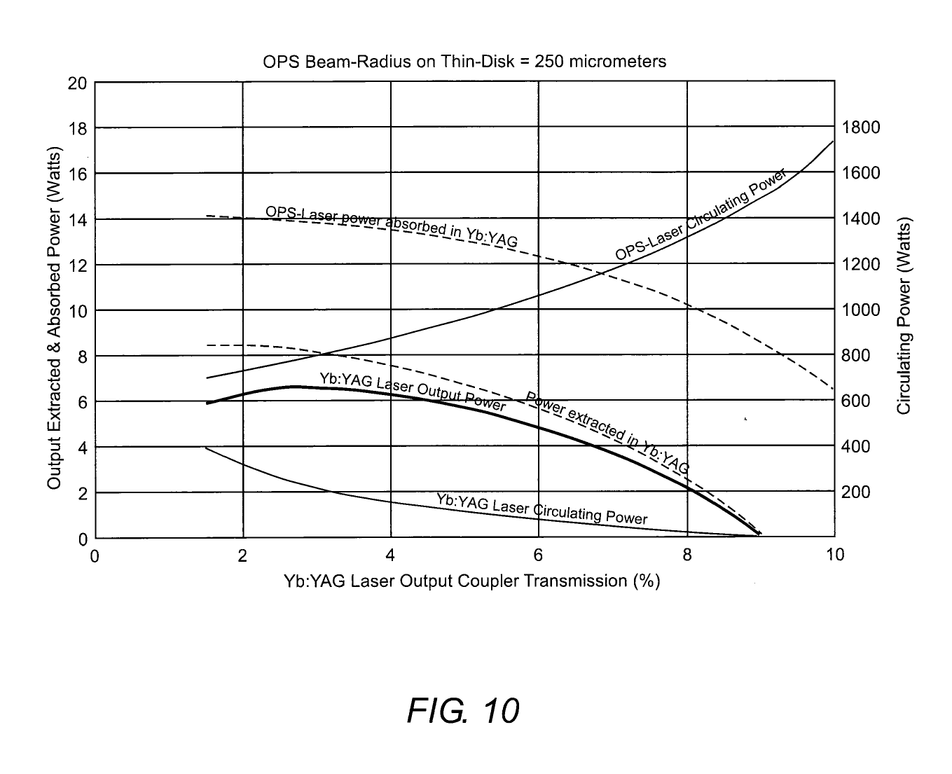

FIG. 10 is a graph similar to the graph of FIG. 8, but wherein the OPS-laser beam radius is assumed to be 250 μm. Here, yet again, the peak power output is again obtained with about 2.5% output coupling from mirror 24 again with about 800 W circulating in resonator 38 and about 250 W circulating in resonator 22. The peak power is somewhat lower than is the case with the 200 μm radius beam.

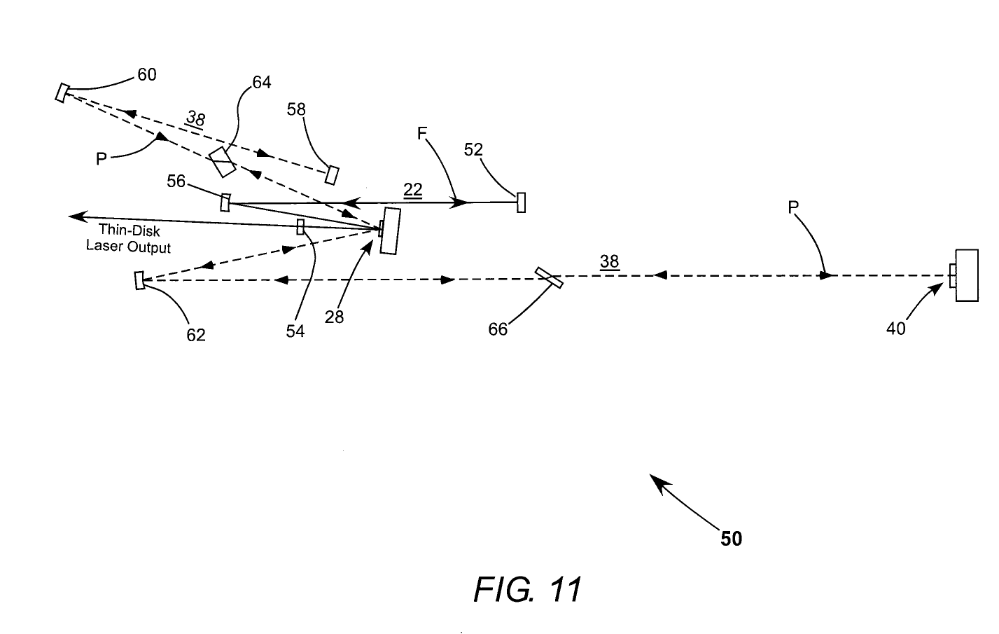

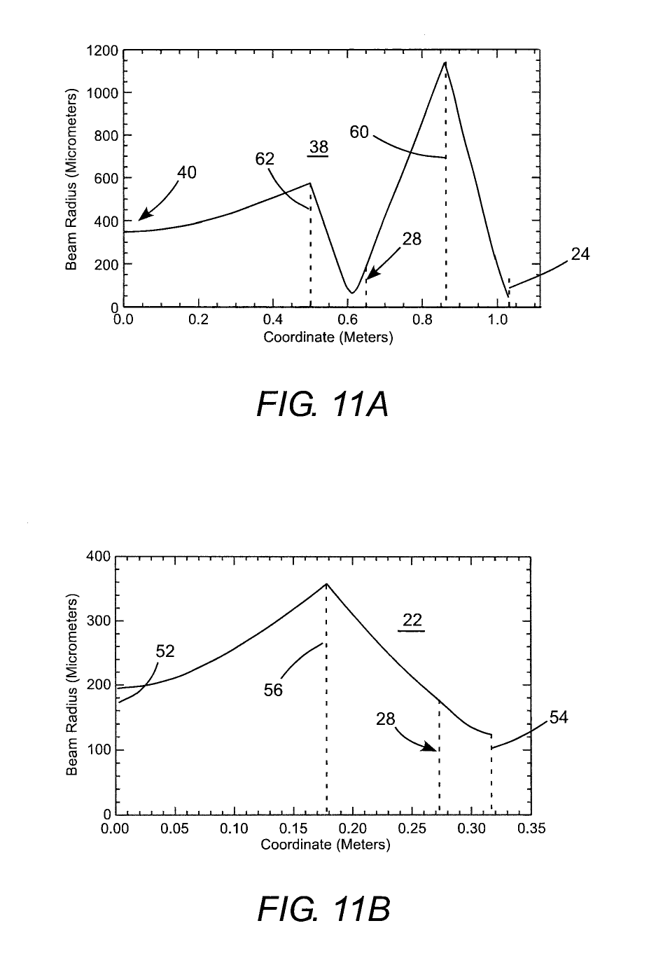

FIG. 11 schematically illustrates layout for experimental apparatus 50 designed to correspond to laser 20 depicted in principle in FIG. 1. Like reference numerals have been retained for certain like components of the two lasers. Spacing between components and incident angles of beams on components are about to scale. In apparatus 50, thin-disk laser resonator 22 is terminated by plane minors 52 and 54 and is folded by a concave minor 56 and active minor 28. The active mirror (thin-disk) gain-medium is Yb:YAG emitting radiation at a wavelength of at 1030 nm. Yb-doping in the disk is at 5% and the disk has a thickness of 280 μm. Minor 54 serves as an output coupling mirror and has a transmission of 97% for the 1030 nm radiation. Mirror 56 has a radius of curvature of 200 mm.

OPS-laser resonator 38 is terminated by OPS chip 40 and a plane mirror 58. Resonator 38 is folded by a concave minor 62, active mirror 28, and another concave minor 60. Minors 60 and 62 each have a radius of curvature of 200 mm. The OPS-chip is configured to have a gain bandwidth centered at a wavelength of about 1010 nm. A birefringent filter (BRF) 66 is provided in resonator 38 for selecting the 1010 nm oscillating wavelength from within the gain-bandwidth of the OPS-chip. A tilted (for Brewster angle incidence) plate 64 is also provided in resonator 38 to compensate for astigmatism introduced in the circulating beam by non-normal incidence reflections from mirrors 60 and 62. The plate has a thickness of 8.0 mm. Some other wavelength-selective element, such as an etalon or a grating, may be used in place of the birefringent filter. However, such other elements may be less effective than the birefringent filter and may require reconfiguration of the resonator.

FIG. 11A and FIG. 11B are mode diagrams for resonators 38 and 22, respectively. The location of reflective components of the resonators is indicted by corresponding reference numerals and the spacing between the reflective components of the resonators can readily be determined from the graphs. The location of BRF 66 and astigmatism-correcting plate 64 is not shown for simplicity of illustration. The exact location of these components is not critical provided that the location is generally as illustrated.

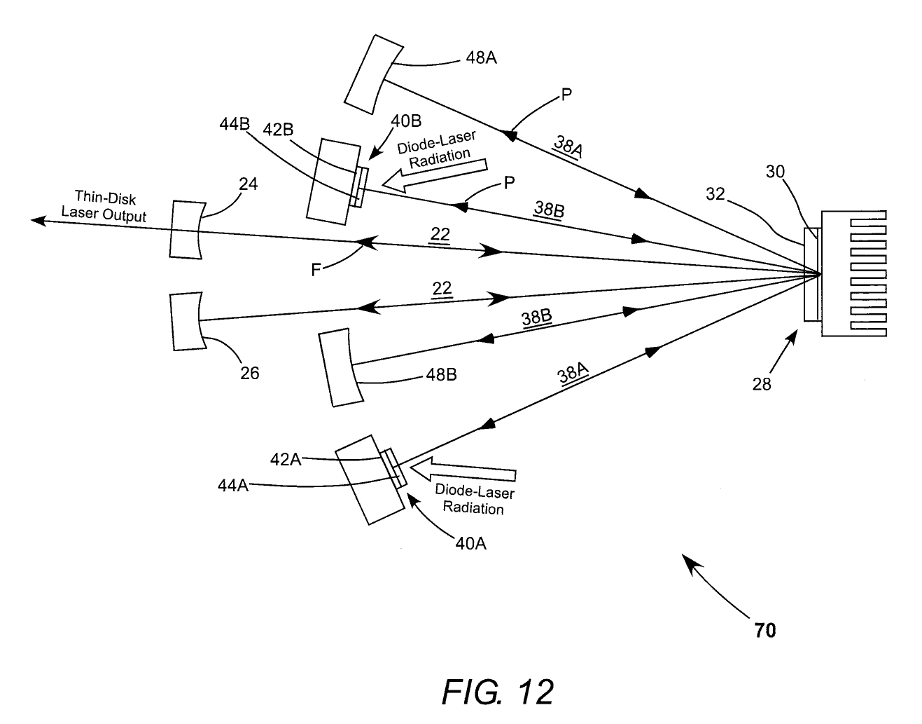

In a situation wherein more thin-disk laser output is required, and wherein circulating OPS laser-resonator power is limited by thermal roll-off of a single OPS-chip, it is possible to increase absorbed OPS-laser power on the thin-disk by utilizing the power of two or more OPS-chips. A description of one arrangement for achieving this is set forth below with reference to FIG. 12.

Here, another preferred embodiment 70 of an OPS-laser pumped thin-disk laser in accordance with the present invention is schematically depicted. Laser 70 is similar to laser 20 of FIG. 1, but includes two OPS-laser resonators, designated as resonators 33A and 38B including OPS chips 40A and 40B respectively. OPS-chips 40A and 40B include mirror-structures 42A and 42B, respectively, surmounted by gain-structures 44A and 44B respectively. OPS-laser resonator 38A is terminated by a concave mirror 48A and minor structure 42A. OPS-laser resonator 38B is terminated by a concave minor 48B and mirror structure 42B. Resonators 38A, 38B and 22 are each once-folded by mirror 30 of active mirror 28 with circulating beams in the resonators being incident at essentially the same location on the active minor. This arrangement can be expected to provide essentially twice the thin-disk laser output of the arrangement of FIG. 1. The wavelength of the radiations circulating in the two OPS laser-resonators can be about the same or different depending, inter alia, on the absorption spectrum of the thin-disk gain-medium.

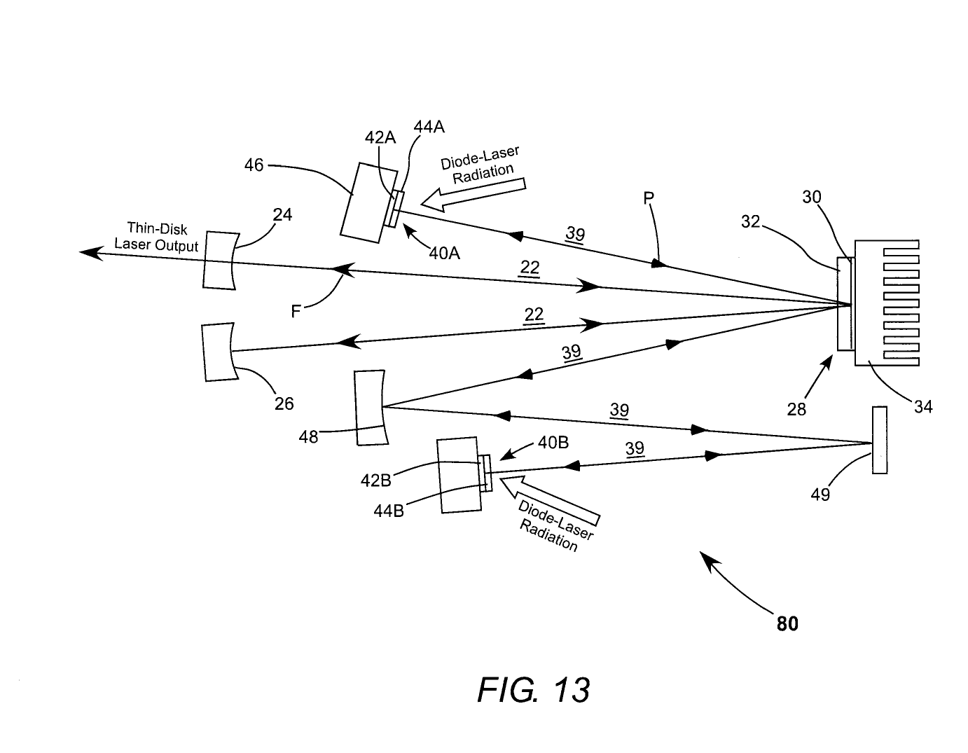

More circulating OPS-laser power could be provided by providing three or more OPS-laser resonators. It may be found useful to make the fold-angle of each of the OPS-resonators equal and arrange the resonator fold-planes of the resonators radially around the active minor. A description of another arrangement for utilizing the power of two or more OPS-laser chips is set forth below with reference to FIG. 13.

Here, yet another preferred embodiment 80 of an OPS-laser pumped thin-disk laser in accordance with the present invention is schematically depicted. Laser 80 is similar to laser 20 of FIG. 1 with an exception that OPS-laser resonator 38 of laser 20 is replaced in laser 80 by a resonator 39 including two OPS-chips 40A and 40B. OPS-chips 40A and 40B include mirror-structures 42A and 42B, respectively, surmounted by gain-structures 44A and 44B respectively.

Resonator 39 is similar to resonator 38 of FIG. 1 with an exception that concave end-minor 48 of resonator 38 is used in resonator 39 at non-normal incidence and forms a reflective optical relay with a plane-mirror 49 and minor-structure 42B of OPS-chip 40B. Resonator 39 is thus terminated by mirror structures 42A and 42B. The optical relay is preferably configured such that the size of the circulating OPS-laser beam is the same on gain-structures 44A and 44B.

Embodiments of the inventive OPS-laser pumped thin-disk laser are described above with reference to a thin-disk laser resonator operated in a continuous-wave mode. The thin disk-laser resonator may also be operated in a pulsed mode, either Q-switched or mode-locked, by providing any common Q-switch such as an acousto-optical (A-O) or electro-optic (E-O) Q-switch in the resonator, or by providing some mode-locking arrangement, active or passive.

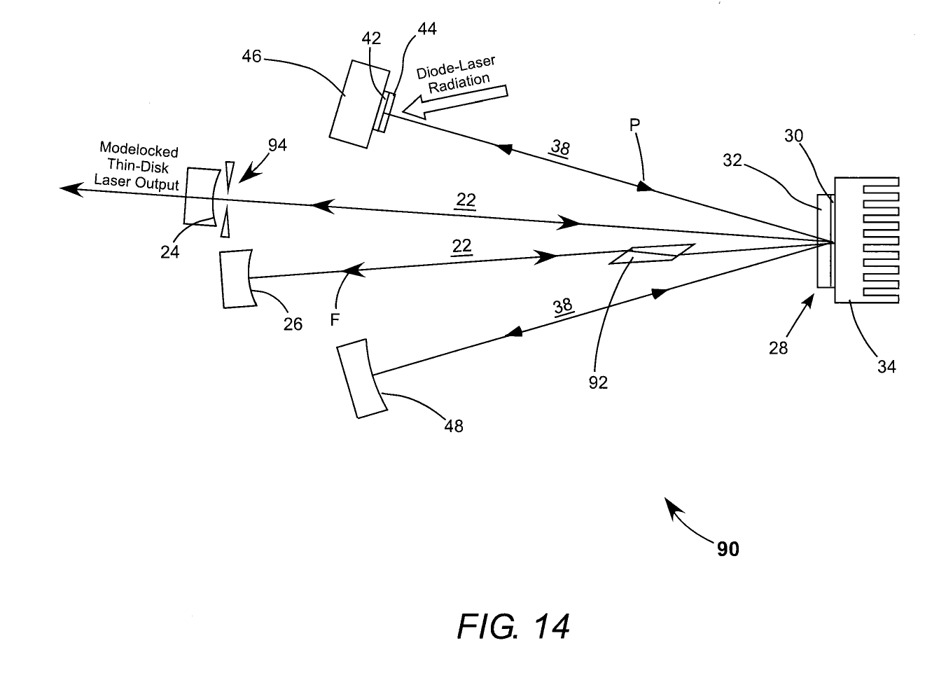

By way of example, FIG. 14 schematically illustrates still yet another embodiment 90 of an OPS-laser pumped thin-disk laser in accordance with the present invention. Laser 90 is similar to laser 20 of FIG. 1 with an exception that in laser 90 thin-disk laser resonator 22 includes an optical element 92 that that has a significant Kerr effect and is arranged, cooperative with an aperture stop 94 adjacent output coupling minor 24 to provide Kerr lens mode-locking (passive mode-locking) of resonator 22. Element 92 is preferably made from a material such as sapphire. Here, element 92 is located close to active minor 28. In the resonator as depicted, this would be near a position of maximum intensity of the circulating radiation, as there would be a beam waist position at or near the minor. This would enhance the Kerr effect. More information on Kerr lens mode-locking can be found in commonly owned U.S. Pat. Nos. 5,079,772 and 5,097,471.

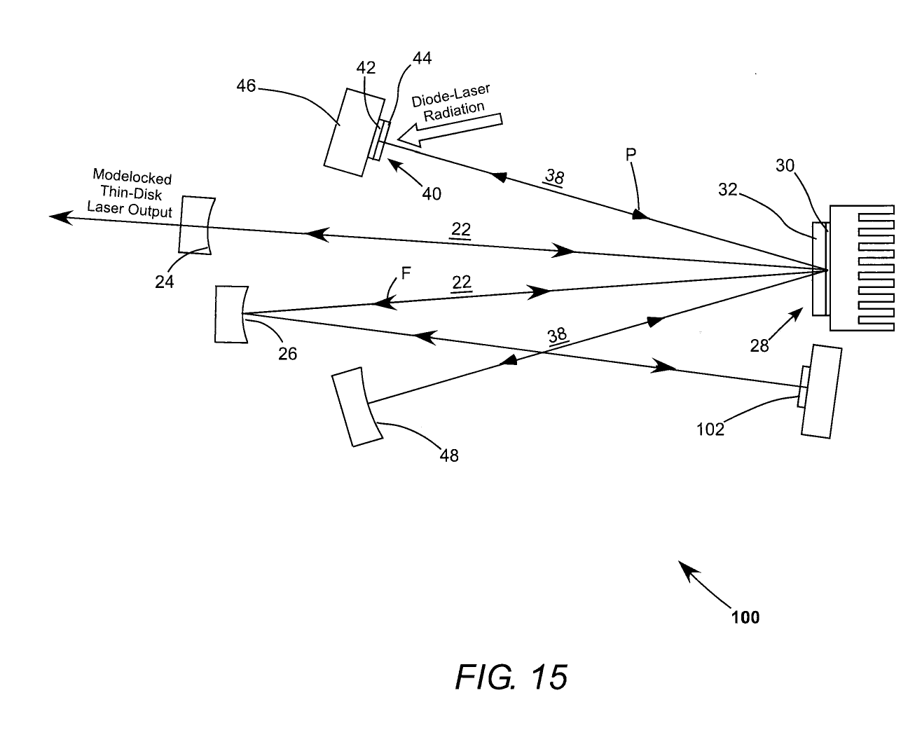

FIG. 15 schematically illustrates a further embodiment 100 of an OPS-laser pumped thin-disk laser in accordance with the present invention. Laser 100 is similar to laser 20 of FIG. 1 with an exception that in laser 100 minor 26 does not terminate thin-disk laser resonator 22 but forms a reflective optical relay with a saturable semiconductor Bragg (SBR) reflector 102. Accordingly, in laser 100, resonator 22 is terminated by output coupling minor 24 and SBR 102. The SBR provides passive mode-locking as is known in the art.

Optimum operation conditions for OPS-laser pumped mode-locked disk lasers in accordance with the present invention can be determined as described above for CW thin disk-lasers. Here, however, the time averaged circulating power of the mode-locked pulsed radiation would be substituted for CW power in the above described analysis.

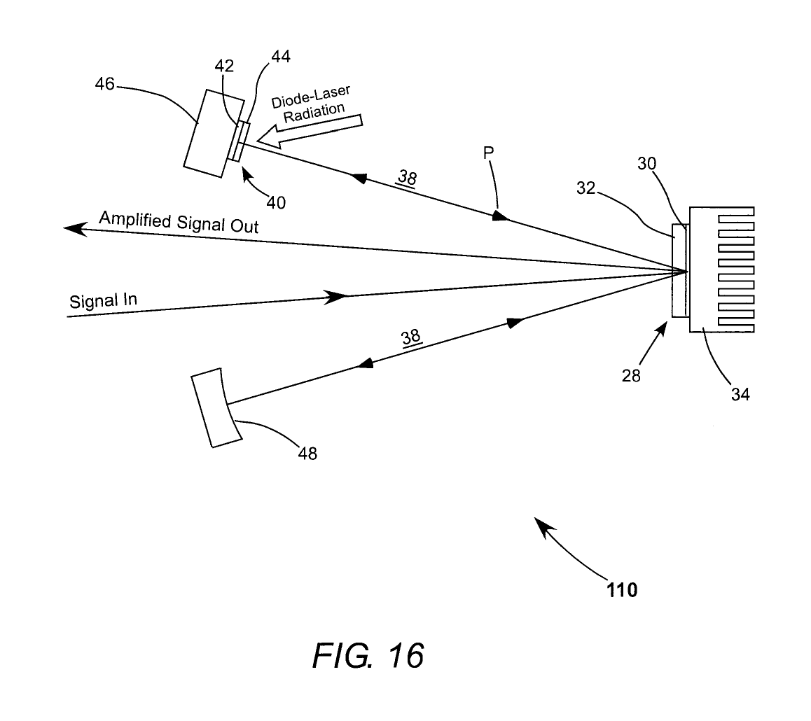

While the present invention is described above in terms of a thin-disk laser resonator resonantly pumped by an OPS laser-resonator, principles of the invention are equally applicable to resonantly pumping a thin-disk optical amplifier with an OPS laser-resonator. One embodiment 110 of such an amplifier is schematically depicted, in principle in FIG. 16. Amplifier 110 is similar to laser 20 of FIG. 1 with an exception that there is no resonator 22 folded by the “active minor” 28. A signal to be amplified is simply directed onto thin-disk gain-element 30 at the point where reflector folds OPS laser-resonator 38. In a more complex arrangement optics could be provided for causing two or more reflections of the signal by the active mirror as is known in the art.

In summary, the present invention is described above in terms of a preferred and other embodiments. The invention is not limited, however, to the embodiments described and depicted. Rather the invention is limited only by the claims appended hereto.

1. Optical apparatus comprising:
a thin-disk solid-state gain-medium surmounting a mirror; and
an arrangement for optically energizing the thin-disk gain medium using radiation circulating in an OPS-laser resonator.

2. The apparatus of claim 1, wherein the thin-disk solid-state gain-medium surmounted mirror is a component of a thin-disk optical amplifier.

3. The apparatus of claim 1, wherein the thin-disk solid-state gain-medium surmounted mirror is a component of a thin-disk solid-state laser-resonator.

4. The apparatus of claim 3, wherein the solid-state and OPS-laser resonators are folded laser-resonators and the thin-disk solid-state gain-medium surmounted mirror is a common fold-mirror of the laser resonators

5. The apparatus of claim 3, wherein the solid-state laser-resonator is a mode-locked laser resonator.

6. Laser apparatus comprising:
a first laser-resonator including at least a first multilayer semiconductor gain-structure;
a first source of optical pump radiation for energizing the semiconductor gain-structure to cause radiation having a first fundamental wavelength characteristic of the semiconductor gain structure to circulate in the first laser-resonator;
a second laser-resonator including a thin-disk, solid state gain-medium surmounting a first resonator mirror, the first resonator mirror providing one resonator mirror of the second laser-resonator; and
wherein the first and second laser resonators are configured and arranged such that the first fundamental-wavelength radiation circulating in the first laser resonator energizes the thin-disk solid-state gain-medium of the second laser-resonator causing fundamental radiation having a second wavelength characteristic of the thin disk solid-state gain-medium to circulate in the second laser resonator.

7. The apparatus of claim 6, wherein a portion of the circulating laser radiation is extracted from the second laser resonator as output radiation of the apparatus.

8. The apparatus of claim 7, wherein the second laser resonator is configured for mode-locked operation and the output radiation of the apparatus is a train of mode-locked pulses.

9. The apparatus of claim 8, wherein the second laser-resonator is configured for Kerr-lens modelocking.

10. The apparatus of claim 8, wherein the second laser-resonator is mode-locked by a semiconductor saturable absorbing element.

11. The apparatus of claim 10, wherein the saturable absorbing element is saturable absorbing reflector and is an end mirror of the second laser resonator.

12. The apparatus of claim 6, wherein the first laser resonator includes a wavelength-selective element for selecting the first fundamental wavelength from a gain-bandwidth characteristic of the semiconductor gain-structure.

13. The apparatus of claim 12, wherein the wavelength-selective element is a birefringent filter.

14. The apparatus of claim 6, wherein the first and second laser resonators are folded laser-resonators, and wherein the first resonator mirror functions as a common fold-mirror for the first and second laser-resonators.

15. The apparatus of claim 14, wherein the first laser-resonator is a thrice-folded laser resonator and the second laser resonator is a twice-folded laser resonator.

16. The apparatus of claim 6, further including a third laser-resonator including a second multilayer semiconductor gain-structure and a second source of optical pump radiation for energizing the second semiconductor gain-structure to cause radiation having a third fundamental wavelength characteristic of the second semiconductor gain-structure to circulate in the third laser-resonator, and wherein the first fundamental-wavelength radiation circulating in the first laser resonator and the third-wavelength fundamental radiation circulating in the third laser resonator energize the thin-disk solid-state gain-medium of the second laser-resonator causing the fundamental radiation having a second wavelength characteristic of the thin disk solid-state gain-medium to circulate in the second laser resonator.

17. The apparatus of claim 16, wherein the first and third fundamental wavelengths are about the same.

18. The apparatus of claim 6, wherein there are first and second multilayer semiconductor gain-structures located in the first laser-resonator and first and second sources of a first source of optical pump radiation for energizing respectively the first and second semiconductor gain-structures to cause the radiation having the first fundamental wavelength to circulate in the first laser-resonator.

19. The apparatus of claim 18, wherein the first and second laser resonators are folded laser-resonators, and wherein the first resonator mirror functions as a common fold-mirror for the first and second laser-resonators.

20. The apparatus of claim 19, wherein the first and second semiconductor gain structures surmount respectively first and second mirror structures and wherein the first laser-resonator is terminated the first and second mirror structures function as end-mirrors of the first laser-resonator.

21. The apparatus of claim 6, wherein the thin-disk gain-medium is Yb:YAG, and wherein the first fundamental wavelength is about 1010 nanometers and the second fundamental wavelength is about 1030 nanometers.

22. An apparatus comprising:
a solid-state gain-medium in the form of thin disk mounted on a disk mirror which is in turn mounted on a heat sink; and
means for exciting said solid-state gain-medium, said means including semiconductor gain-medium which is optically pumped, said semiconductor gain medium being located within a resonator that includes said disk mirror, said disk mirror functioning as one of the mirrors of the resonator, with the optical radiation generated by the semiconductor gain-medium exciting the solid-state gain-medium.

23. An apparatus as recited in claim 22 further including a second resonator surrounding said solid-state gain-medium, said second resonator including an output coupler and at least said disk mirror wherein the solid state gain medium and second resonator define a laser.
